(19) United States
(12) Patent Application Publication
(10) Pub. No.: US 2011/0175503 A1
(43) Pub. Date: Jul. 21, 2011

(54) EQUIPMENT CABINET HAVING IMPROVED SPACE UTILIZATION

(76) Inventors: Aravind Chamarti, Painted Post, NY (US); John David Downie, Painted Post, NY (US); James Scott Sutherland, Corning, NY (US); Richard Edward Wagner, Painted Post, NY (US); Matthew Scott Wagner, Lawrenceville, PA (US)

(21) Appl. No.: 13/122,254

(22) PCT Filed: Nov. 12, 2009
(86) PCT No.: PCT/US09/64123

§ 371 Date: Apr. 1, 2011

(30) Foreign Application Priority Data
Nov. 14, 2008 (US) 61/114628

(51) Int. Cl. H05K 7/18; H05K 5/02; H05K 7/14

(52) U.S. Cl. 312/223.2; 211/26

(57) ABSTRACT

An equipment cabinet (2) includes a front wall (4), a side wall (6,8), and an equipment rack (20) having a width (28) and a front face plane (32). The front wall includes a front opening (16) having a width (18). The width of the rack is approximately equal to or larger than the width of the front opening. A space (14) is disposed between the rack and the side wall, and between the rack and the front wall. A mounting bracket (40) includes a plate (42) and a protrusion (44), wherein the plate is coupled to one of the rack, the front wall and the side wall. The protrusion is disposed in the space, and includes a substantially planar surface (45) that is neither parallel to, nor in the same plane as, the front face plane. A patch panel (50), an adapter module (54), RFID components (60), or an RFID reader and/or reader antenna (64), may be coupled to the protrusion.

### BACKGROUND

The present invention relates to data center equipment cabinets and, in particular, to data center equipment cabinets having improved space utilization.

### TECHNICAL BACKGROUND

In a data center, equipment cabinets may be used to mount equipment. An equipment rack is disposed within the equipment cabinet, leaving narrow vertical spaces to the sides of the equipment rack, between the equipment rack and the cabinet walls. When a front access opening in the cabinet has a width that is less than or equal to the width of the equipment rack, it is very difficult to access and utilize the narrow vertical spaces to the left and right of the equipment rack. Accordingly, oftentimes, this space goes unutilized, thereby increasing the necessary square footage of a data center. And data center operating costs are generally proportional to the square footage of floor space occupied by equipment cabinets. Therefore, unutilized cabinet space increases data center operating costs. Further, the relative dimensions of the access opening and the width of the equipment rack may make it difficult to access sockets on the back of the rack-mounted equipment. This problem may be exacerbated when the narrow vertical spaces to the left and right of the equipment rack are used for routing cables and/or cooling air to rack-mounted equipment.

Additionally, when both RFID tags and RFID reader antennas are mounted in the central rack space, an attempted RF signal transmission between the two may be blocked by electronic equipment, especially shielded equipment, also mounted in the central rack space.

### SUMMARY

According to one aspect, there is provided an equipment cabinet having an equipment rack and cabinet walls surrounding the equipment rack. The equipment rack is accessible by an opening in one of the cabinet walls. The equipment rack includes vertical rails, defining a virtual front face plane, to which equipment housings may be mounted. Additionally, there is provided a mounting bracket positioned to increase space utilization within the equipment cabinet, and configured to facilitate access to the equipment disposed in the cabinet. The mounting bracket includes a plate and a protrusion extending from the plate. The plate may be coupled to the equipment rack or to the cabinet walls, so that the protrusion is disposed between the equipment rack and the cabinet walls. Devices may then be coupled to the protrusion, thereby enabling installation of additional equipment in the cabinet without consuming valuable central rack space. For example, the number of patch panels, or connection housings disposed within the central rack space may be reduced or eliminated, thereby allowing more central rack space for equipment. Utilization of this otherwise unused space on the sides of the cabinet can reduce the number of cabinets necessary for a particular data center and, thereby, reduce the overall cost of the data center, because the total square footage dedicated to network equipment can be reduced.

The protrusion is disposed at an angle relative to the front face plane of the rack so that the devices mounted to the protrusion are easily accessible from the front opening in the cabinet, even when the width of the front opening is substantially the same size as, or smaller than, the width of the rack. Patch panels, adapter modules, or similar devices, for example, may be coupled to the mounting bracket and connected to the rack-mounted equipment so as to present sockets that would normally appear on the back side of rack-mounted equipment on the front side of the cabinet for easy access by trades.

According to another aspect, radio frequency identification (RFID) hardware may be coupled to the mounting bracket to improve interrogation of RFID tags, or to retrofit/upgrade RFID applications where equipment must be added to cabinets that are already very full. That is, the space in the cabinet outside the central rack space may be used as a communication channel among elements used to facilitate identification of components within the cabinet. The RFID hardware may include, for example, RFID tags integrated into the plugs, sockets, or adapter modules, coupled to the mounting bracket. Alternatively, or in addition, to the foregoing, the RFID hardware and/or may include one or more RFID readers and/or reader antennas, for example. Still further, alternatively or in addition to the foregoing, the RFID hardware may include elements for sending or receiving signals used to identify other elements within the cabinet, for example. When RFD tags integrated into plugs, sockets, or adapter modules, are coupled to the mounting bracket, they may be positioned in a location where they receive more RF signal strength from RFID reader antennas located within the cabinet. That is, the RFID tags may be positioned at a location wherein they have a more direct line of communication with an RFID reader antenna with reduced interference from an intervening piece of equipment. Similarly, an RFID reader antenna may be coupled to a mounting bracket and positioned at a location adjacent to a rack-mounted housing having therein patch panels, sockets, and/or adapters, with RFID tags. In the case of retrofitting or upgrading RFID capability in an already full cabinet, devices including either one, or both, RFID tags and RFID readers and/or reader antennas may be coupled to mounting brackets and positioned in otherwise unutilized space between the equipment rack and cabinet walls.

According to another aspect, there is provided an equipment cabinet. The equipment cabinet includes a front wall having a front opening therein, the front opening having a width. A side wall is coupled to the front wall. An equipment rack is disposed adjacent to the front wall and to the side wall, the equipment rack having a width, wherein the width of the equipment rack is approximately equal to or larger than the width of the front opening. The equipment rack has a front face plane facing the front opening. A space is disposed between the equipment rack and the side wall, and between the equipment rack and the front wall. A mounting bracket includes a plate and a protrusion, wherein the plate is coupled to one of the equipment rack, the front wall and the side wall, so that the protrusion is disposed in the space. Further, the protrusion has a substantially planar surface that is neither parallel to, nor in the same plane as, the front face plane.

According to another aspect, there is provided an equipment cabinet having RFID hardware. The equipment cabinet includes an equipment rack including vertical rails that define a central rack space. A mounting bracket includes a plate and a protrusion, wherein the plate is coupled to one of the vertical rails so that the protrusion is disposed outside of the central rack space. RFID hardware is coupled to the protrusion. The RFID hardware may include RFID tags, RFID readers and/or reader antennas, for example. Further, a piece of electromagnetically shielded equipment may be disposed in the central rack space.

According to another aspect, there is provided an equipment cabinet including an equipment rack, an outer structure, and a mounting bracket. The equipment rack includes a central rack space. The outer structure is coupled to the equipment rack and is disposed outside the central rack space. A space is disposed outside of the central rack space and is defined by the equipment rack and the outer structure. The mounting bracket includes a plate and a protrusion, wherein the plate is coupled to one of the equipment rack and the outer structure so that the protrusion is disposed in the space. Further, RFID hardware is coupled to the protrusion.

The RFID hardware may include at least one of an RFID tag and an RFID reader antenna. In one instance, the RFID hardware includes an RFID tag, and the equipment cabinet further comprises an RFID reader antenna disposed so as to emit RFID signals into the space. In another instance, the RFID hardware includes an RFID reader or reader antenna, and an RFID tag is mounted elsewhere in the cabinet.

The outer structure may include a wall.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework to understanding the nature and character of the invention as it is claimed.

The accompanying drawings are included to provide a further understanding of principles of the invention, and are incorporated in and constitute a part of this specification. The drawings illustrate one or more embodiment(s), and together with the description serve to explain the principles and operation of the invention. It is to be understood that the various features of the invention disclosed in this specification and in the drawings can be used in any and all combinations.

### BRIEF DESCRIPTION OF THE DRAWINGS

FIG. 1 is an orthographic view of an equipment cabinet.

FIG. 2 is a schematic top-view of an equipment cabinet as taken along line 2-2 in FIG. 1.

FIG. 3 is an orthographic view of a mounting bracket.

FIG. 4 is a detailed view of a mounting bracket disposed in the equipment cabinet.

FIG. 5 is a schematic front view of a piece of equipment connected to a patch panel.

FIG. 6 is a schematic rear view of a piece of equipment connected to a patch panel.

FIG. 7 is an orthographic view of a patch panel and an adapter module.

FIG. 8 is an orthographic view of a portion of an equipment cabinet having RFID hardware mounted therein.

### DETAILED DESCRIPTION

In the following detailed description, for purposes of explanation and not limitation, example embodiments disclosing specific details are set forth to provide a thorough understanding of the principles of the present invention. However, it will be apparent to one having ordinary skill in the art, having had the benefit of the present disclosure, that the present invention may be practiced in other embodiments that depart from the specific details disclosed herein. Moreover, descriptions of well-known devices, methods and materials may be omitted so as not to obscure the description of the principles of the present invention. Finally, wherever applicable, like reference numerals refer to like elements.

The term “cable” as used herein may be, for example, an optical fiber cable and may include one or more optical fibers therein.

According to one aspect, there is provided an equipment cabinet having an equipment rack and cabinet walls. The equipment rack includes a front face plane facing a front opening in the equipment cabinet, and a central rack space in which equipment is mounted. A mounting bracket is positioned to increase space utilization within an equipment cabinet, and configured to facilitate access to the equipment disposed in the cabinet. The mounting bracket includes a plate and a protrusion extending from the plate. The plate may be coupled to the equipment rack or to the walls of the cabinet, so that the protrusion is disposed between the equipment rack and the cabinet walls. Devices may then be coupled to the protrusion, thereby enabling installation of additional equipment in the cabinet without consuming valuable central rack space. For example, patch panels, adapter modules, and RFID hardware may be coupled to the protrusion.

The protrusion is disposed at an angle relative to the front face plane of the rack so that the devices mounted to the protrusion are easily accessible from the front opening in the cabinet, even when the width of the front opening is substantially the same size as, or smaller than, the width of the rack.

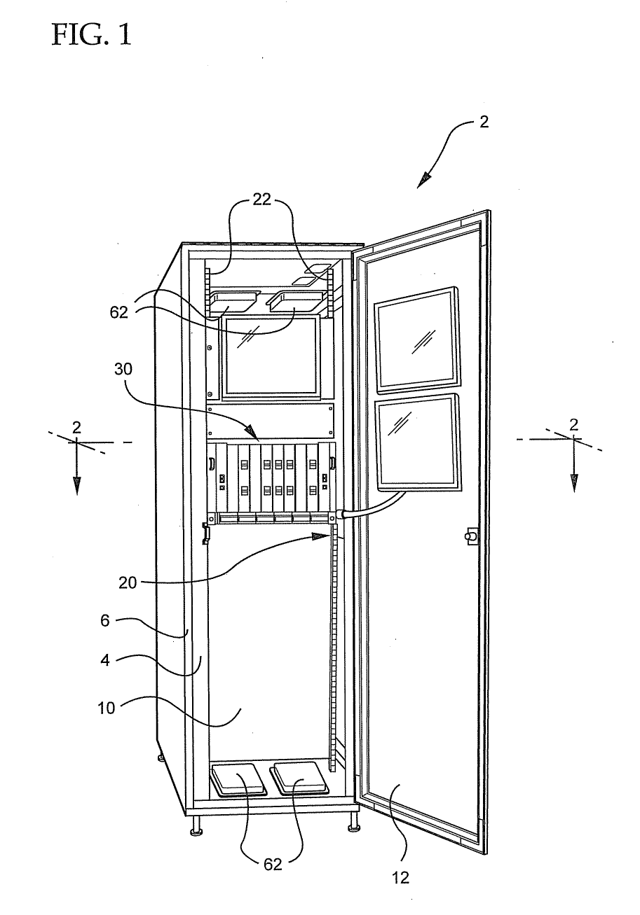

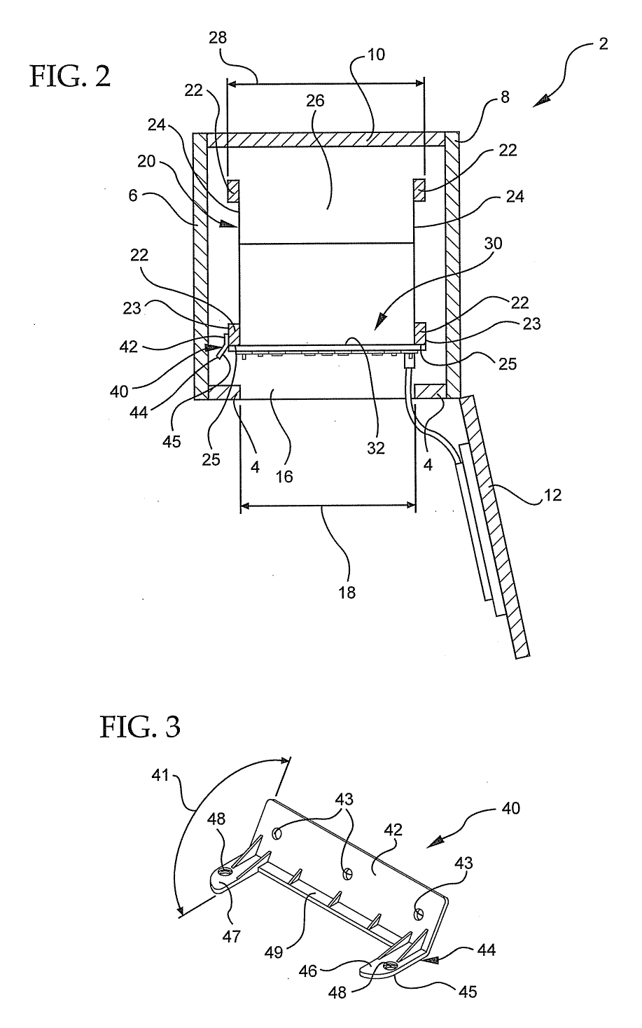

FIGS. 1 and 2 show one embodiment of an equipment cabinet 2 having an equipment rack 20 for mounting equipment 30. A mounting bracket 40 is disposed within the equipment cabinet 2 in order to improve space utilization within the equipment cabinet 2 and, thus, utilization of the square footage of the data center floor space occupied by equipment cabinets 2. That is, by improving space utilization within the equipment cabinet 2, fewer equipment cabinets 2 will be necessary for a particular data center.

Equipment cabinet 2 includes a front wall 4, a side wall 6, a second side wall 8, and a back wall 10. The front wall 4 is coupled to the side wall 6 and second side wall 8. Additionally, the front wall 4 has a front opening 16 having a width 18. A door 12 is sized and configured to cover the front opening 16. The back wall 10 is also coupled to the side wall 6 and the second side wall 8, and is disposed opposite to the front wall 4. Any suitable manner of coupling the walls 4, 6, 8, and 10, may be used. For example, although not shown, four vertically extending posts may be disposed at the four corners of the equipment cabinet 2, and the walls may be coupled to the vertically extending posts. Alternatively, for example, the walls may be directly coupled to one another.

Equipment rack 20 is disposed in the equipment cabinet 2 whereby the front wall 4, side walls 6, 8, and back wall 10, are disposed around the equipment rack 20. The equipment rack 20 includes four vertical rails 22, horizontal rails 24, and a central rack space 26 within the bounds defined by the vertical rails 22. The rack 20 has a width 28 defined by two vertical rails 22 that are disposed adjacent to opposite side walls 6,8 of the equipment cabinet 2. The width 28 of the rack 20 is substantially equal to, or larger than, the width 18 of the front opening 16.

Each vertical rail 22 has a side surface 23 facing the interior of a wall of the equipment cabinet 2. Each vertical rail 22 may also have a front surface 25. The vertical rails 22 at the front of the equipment cabinet 2 define a virtual front face plane 32 that faces the front opening 16. The front face plane 32 may be generally coplanar with at least one point on each front surface 25 of the vertical rails 2 at the front of the equipment cabinet.

A horizontal rail 24 may be coupled to two vertical rails 22. A horizontal rail 24 may be coupled to two vertical rails 22 disposed adjacent to one of the side walls 6, 8, so that the horizontal rail 24 extends substantially parallel to that side wall. Alternatively, or in addition to the foregoing, a horizontal rail 24 may be coupled to two vertical rails 22 disposed adjacent to the front wall 4 or to the back wall 10, so that the horizontal rail 24 extends substantially parallel to the front wall 4 or to the back wall 10. Further, a horizontal rail 24 may be coupled to two other horizontal rails 24. Any suitable number of horizontal rails 24 may be used at any suitable position along the length of the vertical rails 22.

A space 14 is defined between the rack 20 and the equipment cabinet 2. More specifically, space 14 is disposed between the outer surfaces 23, 25 of the vertical rails 22 and the inner surfaces of the side walls 6, 8, as well as between the outer surfaces 23, 25 of the vertical rails 22 and the inner surfaces of the front wall 4 and the back wall 10. Stated another way, the space 14 is disposed outside of the central rack space 26.

A piece of equipment 30 is mounted to the equipment rack 20 and is disposed in the central rack space 26. The piece of equipment 30 may be coupled to either the vertical rails 22, the horizontal rails 24, or any combination thereof. The piece of equipment 30 faces toward the front opening 16 so that the equipment may be accessed by trades. The piece of equipment 30 may be any type of telecommunications equipment (and/or other equipment), for example, a blade server mainframe, a disk drive array, an Ethernet switch, a SAN controller, or a communications switch. Further, the piece of equipment 30 may be one that has at least a portion of its interior components shielded from electromagnetic energy.

The mounting bracket 40 includes a plate 42, and a protrusion 44 coupled to the plate 42. As shown in FIG. 2, the plate 42 is coupled to the equipment rack 20, more specifically to the side surface 23 of a vertical rail 22. Alternatively, the plate 42 may be mounted to the front surface 25 of a vertical rail 22. As a further alternative, the plate 42 may be coupled to the front wall 4, to the side wall 6, or to a member supporting the front 4 and/or side 6 walls. The protrusion 44 includes a substantially planar surface 45. The mounting bracket 40 is disposed so that the substantially planar surface 45 is disposed in the space 14. In some embodiments, the planar surface 45 may be disposed so as to be neither parallel to, nor in the same plane as, the front face plane 32 of the equipment rack 20. The arrangement, wherein the planar surface 45 is disposed so as to be neither parallel to, nor in the same plane as, the front face plane 32 of the equipment rack 20 facilitates access to the devices mounted to the bracket 40 when the width 28 is substantially equal to or larger than the width 18. Such facilitated access is particularly useful when the bracket 40 is used to mount devices, for example patch panels or adapter modules, to which cables may be repeatedly connected and disconnected.

As shown in more detail in FIG. 3, the plate 42 includes holes 43 disposed therein, for mounting the bracket 40. The protrusion 44 may include one or more of a first leg 46, a second leg 47, and a spine 49, and defines the substantially planar surface 45. Holes 48 may be disposed in the first 46 and/or second 47 legs so that other elements may be coupled to the protrusion 44. The first 46 and second 47 legs may be of any suitable length, so as to accommodate various different devices that may be mounted thereto. Additionally, the mounting bracket 40 may be configured to mount more than one device, wherein the devices are adjacent to one another in a side-by-side, and/or end-to-end relationship. Further, although the protrusion 44 is shown as having a spine 49 and legs 46, 47, in an open “C” configuration, the ends of the legs may be connected by another portion to form a configuration resembling a plate having a rectangular mounting opening therein. The bracket 40 may be made out of any suitable material, however, non-metal materials are preferred so as to minimize interference with RF energy in the event that bracket 40 is used to mount devices that include RFID hardware.

The substantially planar surface 45 is disposed at an angle 41 with respect to the plate 42. The angle 41 may be any suitable angle. In some embodiments, the angle 41 is chosen so that when the plate 42 is mounted either to the equipment rack 20 or to the cabinet 2, the substantially planar surface 45 is not disposed in the same plane as, nor parallel to, the front face plane 32. For example, when the plate 42 is mounted to the side surface 23 of a vertical rail 22, as shown in FIG. 2, the angle 41 may be an angle other than 90 degrees. Preferably, in this same situation, the angle 41 is greater than 90 degrees so that the substantially planar surface 45 is easily accessible from the front opening 16, particularly when the width 18 of the front opening 16 is less than the width 28 of the rack 20. Thus, when the substantially planar surface 45 is easily accessible from the front opening 16, devices mounted to the protrusion 44 also will be easily accessible from the front opening 16. This arrangement, wherein the substantially planar surface 45 is not disposed in the same plane as, nor parallel to, the front face plane 32, is further beneficial when the mounting bracket 40 is used to hold a device (for example a patch panel or adapter module) to which cables may be regularly connected and disconnected. As an alternative example, the plate 42 of mounting bracket 40 may be coupled to the front surface 25 of a vertical rail 22, wherein the angle 41 may be substantially 90 degrees or less so that the protrusion 44 is disposed in the space 14.

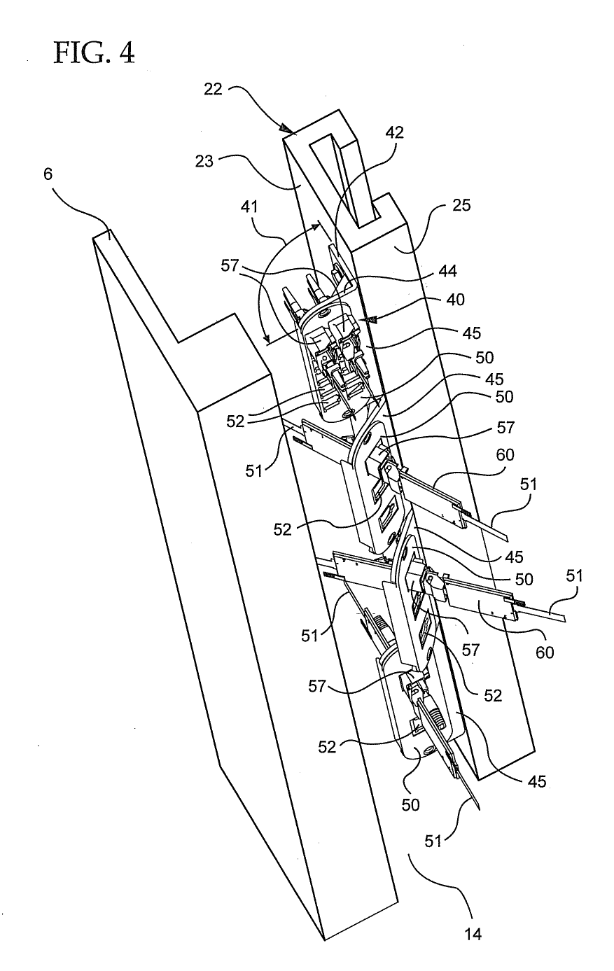

Although only one mounting bracket 42 is shown in FIG. 2, any suitable number of mounting brackets 40 may be used, and may be mounted to any suitable vertical rail 22 in the equipment rack 20. For example, mounting brackets 40 may be mounted to one or both vertical rails 22 that are closest to the front wall 4. Additionally, as shown in FIG. 4 for example, more than one mounting bracket 40 may be coupled to one vertical rail 22. Further, all the mounting brackets 40 on one vertical rail 22 may be disposed so as to have their substantially planar surfaces 45 aligned with one another, e.g., all the brackets 40 have the same angle 41. On the other hand, the mounting brackets 40 on one vertical rail 22 may have different angles 41 so that some of the substantially planar surfaces 45 are not aligned with one another, i.e., some of the substantially planar surfaces 45 are not in the same plane. However, for ease of use, for the brackets 40 mounted to one vertical rail 22, it is preferred to have the substantially planar surfaces 45 in substantially the same plane.

Next, the operation and use of the equipment cabinet 2 and mounting bracket 40 will be explained.

When the width 28 of the equipment rack 20 is substantially the same as, or larger than, the width 18 of the front opening 16, it is difficult for trades to access space 14, let alone utilize the space 14. Accordingly, the mounting bracket 40 may be employed not only to utilize this space 14 but to facilitate access to the devices mounted in the space 14. Devices that may be mounted in space 14 include patch panels 50, adapter modules 54, and RFID hardware, for example.

As shown in FIG. 4, the mounting bracket 40 may be used to mount a patch panel 50 in the space 14. The patch panel 50 includes sockets 52 into which plugs 57 are inserted. The sockets 52 may be configured to receive any type of plug 57, for example, MTP, LC, or SC connectors. Although only one patch panel 50 is shown as being coupled to one mounting bracket 40, any suitable number of patch panels 50 may be so coupled, depending on the size of the first 46 and second 47 legs, and/or spine 49, and depending upon the dimensions of the space 14. Cables 51 may then be connected to the sockets 52 on the patch panel 50. The cables 51 may include RFID components 60. The RFID components 60 may include RFID tags that are used to determine whether or not a sufficient connection has been made between the cable 51 and the socket 52, or simply to identify a cable 51. See, for example, WO2008/054742 A2, filed Oct. 30, 2007. The cables 51 connected to the patch panels 50 as shown in FIG. 4, may then be connected to other patch panels 50, to a piece of equipment 30 in the rack 20, or to other devices.

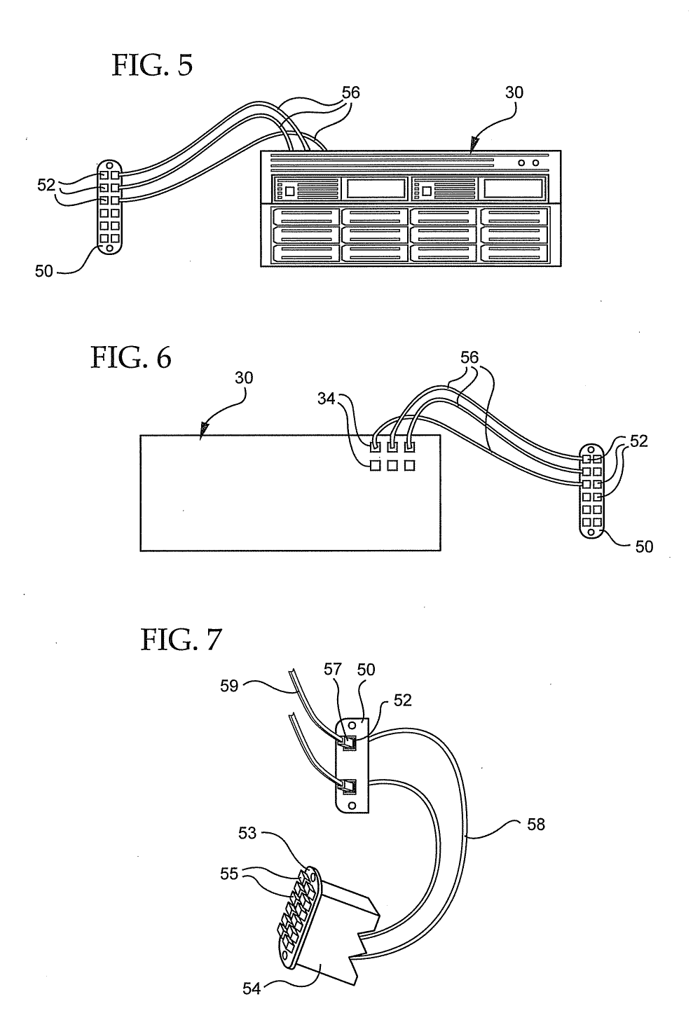

As shown in FIGS. 5 and 6, the patch panel 50 may be used to provide front-panel access to backside equipment sockets. On the patch panel 50, there are disposed pairs of connected sockets 52, wherein the sockets 52 in each pair are of the same type, for example, two-fiber sockets. In each pair of sockets 52, one socket 52 is disposed on the front of the patch panel 50, and the other socket 52 is provided on the rear of the patch panel 50. A cable 56 is plugged into a socket 34 on the rear-side of the equipment 30 and into a socket 52 on the rear side of the patch panel 50. When the patch panel 50 is mounted in mounting bracket 40, the corresponding socket 52 on the front of the patch panel 50 then provides an easy-access connection to the socket 34 disposed on the rear of equipment 30. In this manner, using a suitable number of patch panels 50, any number of sockets 34 from the rear of the equipment 30 may be easily accessed from the front opening 16. Although one patch panel 50 is shown as receiving cables 56 connected to only one piece of equipment 30, one patch panel 50 may receive cables 56 connected to any suitable number of pieces of equipment 30. Cables 56 may include any suitable number of fibers therein, for example cables 56 may each be two-fiber cables.

The bracket 40 may be used to mount an adapter module 54, as shown in FIG. 7, in the space 14. A face plate 53 on the adapter module 54 may be coupled to the bracket 40. The adapter module 54 may have, for example, an MTP/LC/SC connector function. The mounting bracket 40 may be suitably sized to mount more than one adapter module.

For example, the adapter module 54 may have two cables 58 extending from one side of the adapter module 54, wherein the end of each cable 58 not connected to the adapter module 54 has an MTP connector. The cables 58 may be twelve-fiber cables, for example. The other side of the adapter module 54 may then have a sockets 55 of a different connection type, for example LC. Any desired device or equipment may be plugged into a socket 55. Each of the sockets 55 may be a two-fiber socket, and is connected to selected ones of the fibers from the cables 58.

Cables 58 from the adapter module 54 may be plugged into respective sockets 52 on the back side of a patch panel 50 similar to the patch panel 50 as described above. A corresponding socket 52 on the front side of the patch panel 50 may then be connected to another cable 59. Cable 59 may be a twelve-fiber trunk cable for example. Selected fibers from the cable 59 may then be connected to any desired device, for example, a piece of equipment 30 in the equipment cabinet 2, a piece of equipment in another equipment cabinet, or a hand-held device, as follows. The fibers in a cable 59 are connected to the cables 58 of an adapter module 54 by mutual connection to the patch panel 50. The adapter module 54 then separates selected pairs of fibers from the cables 58 to each socket 55. Cables connected to the sockets 55 may then be plugged directly into equipment 30 (or other equipment either in the same or a different equipment cabinet), or into other patch panels 50 (as shown in FIGS. 5 and 6, for example) whereby cables 56 then ultimately connect to the equipment 30.

When the bracket 40 is used to mount devices (for example patch panels or adapter modules) to which cables may be repeatedly connected and disconnected, and when the width 28 is substantially the same as or greater than the width 18, access to the devices is facilitated by disposing the substantially planar surface 45 so that it is neither in the same plane as, nor parallel to, the front face plane 32.

Radio frequency identification (RFID) hardware may be coupled to the mounting bracket 40 to improve interrogation of RFID tags, or to retrofit/upgrade RFID applications where equipment must be added to cabinets that are already very full. RFID hardware may include, for example, RFID tags, RFID readers, or RFID reader antennas. For example, the mounting bracket 40 may be used to mount at least one of RFID tags and RFID reader antennas. That is, one mounting bracket 40 may be used to mount one or more RFID tags, whereas one or more RFID reader antennas are disposed elsewhere in the cabinet. In this situation, the RFID reader antenna may be disposed so as to emit RFID signals into the space in which the tag is located. By way of another example, the mounting bracket 40 may be used to mount one or more RFID reader antennas, whereas one or more RFID tags are located elsewhere in the cabinet 2. By way of still further example, one mounting bracket 40 may be used to mount both one or more RFID tags and one or more RFID antennas. By way of still further example, one mounting bracket 40 may be used to mount one or more RFID tags, whereas a second mounting bracket 40 may be used to mount one or more RFID reader antennas.

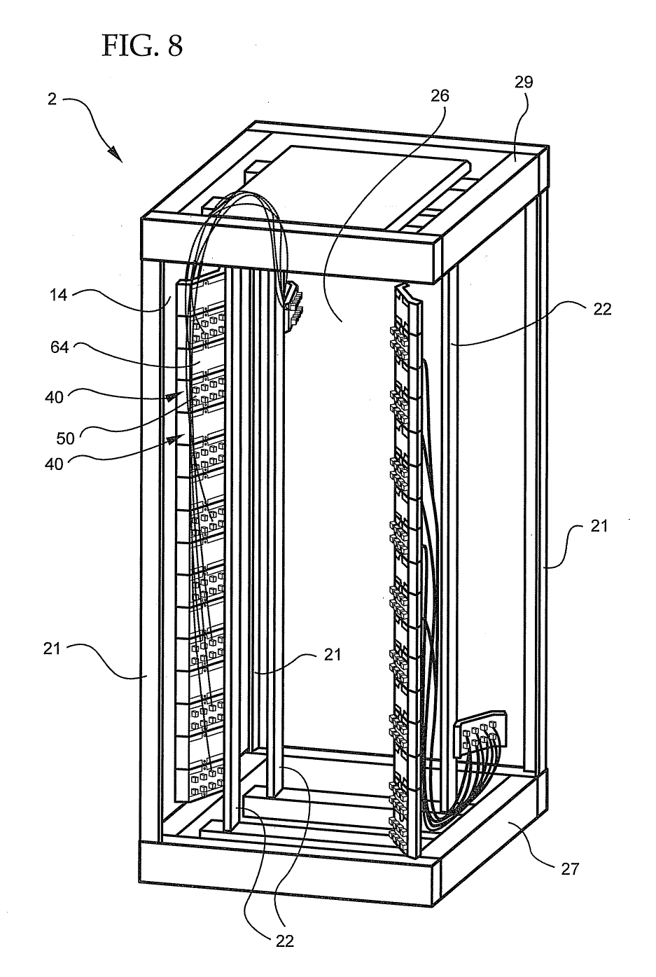

According to one embodiment, as shown in FIG. 8, a mounting bracket 40 may be used to mount RFID hardware in the space 14. The RFID hardware may include, for example: RFID components 60 on cables 51 or on sockets 52, 55 (see FIG. 4, for example); or RFID readers or reader antennas 64. When mounting RFID components 60 on cables 51 or sockets 52, 55, and when the width 28 is substantially the same as or greater than the width 18, then as noted above it is advantageous to have the substantially planar surface 45 neither in the same plane as nor parallel to the front face plane 32. On the other hand, when mounting RFID readers or reader antennas 64, the disposition of the substantially planar surface 45 relative to the front face plane 32 is not particularly limited. However, in the case of retrofitting RFID readers or reader antennas 64 to an already full cabinet, it may be beneficial to dispose the substantially planar surface 45 so that it is neither parallel to nor in the same plane as the front face plane 32 so as to facilitate installation or to provide a more advantageous placement of the reader and/or reader antenna 64 with respect to the RFID components 60 to be detected.

Referring back to FIG. 4, cables 51 may include RFID components 60 that may include RFID tags. For example, cables 51 shown in FIG. 4 may be: the cables 56 between the equipment 30 and a patch panel 50; jumper cables between a patch panel 50 and an adapter module 54; cables 58 between adapter module 54 and a patch panel 50; and/or cables from a cable 59. The sockets 52, 55, may also include RFID components that assist in determining whether a valid connection has been made, or simply to identify the sockets themselves. When the cables 51 from the equipment 30 are routed to the patch panels 50 or adapters 54 positioned in space 14, the RFID components 60 can be positioned in a location where they receive more RF signal strength from RFID reader antennas located within the cabinet 2. RFID reader antennas 62 may be located at the top and bottom of the equipment as shown in FIG. 1, for example. When on the top and bottom of the cabinet 2, the antennas 62 may be located within the central rack space 26, or may be positioned more outwardly towards the side walls 6, 8, so that at least a portion thereof lies outside the central rack space 26. Alternatively, the RFID reader antennas may be mounted on the side walls 6, 8, or the back wall 10 of the cabinet 2. Still further, alternatively, the RFID reader or reader antennas 64 may be mounted in a housing within the rack. In this case, the mounting bracket 40 advantageously may be used to mount other RFID hardware, RFID tags for example, adjacent the housing in which the RFID reader or reader antennas 64 are located. In any case, the RFID reader antennas advantageously may be disposed in the cabinet so as to emit RFID signals into the space where other RFID hardware, for example RFID tags, are located.

Referring back to FIG. 8, alternatively or in addition to mounting the RFID components 60 in the space 14, one or more RFID readers or reader antennas 64 may be mounted in the space 14. Mounting an RFID reader or reader antenna 64 in space 14 allows interrogation of the RFID components 60 on the cables 51 or sockets 52, 55 that are disposed either within space 14 or within a rack-mounted housing (i.e., a housing mounted within central rack space 26) near the reader antenna 64. This can be important when equipment mounted in the central rack space blocks RF signals from RFID reader antennas 62 located in the top and bottom of the equipment cabinet 2. Stated another way, for example, suppose the equipment cabinet configuration includes: (a) a piece of shielded equipment, for example a piece of equipment having at least a portion of its interior components shielded from electromagnetic energy, mounted in the central rack space; (b) RFID reader antennas 62 at the top and bottom of the cabinet; and (c) one or more RFID-based housings mounted in the central rack space and having patch panels, connectors, and/or adapters, with RFID tags. If the shielded equipment must be positioned between an RFID reader antenna and the RFID-based housings, then RFID tags within the rack-mounted housings may not receive sufficient RF power. In this case, for example, it would be beneficial to position RFID reader antennas 64 in the space 14 adjacent to the RFID-based rack-mounted housing. The design of the RFID-based housing may need to be modified with one or more side openings to allow side access of RF signals.

Further, the placement of RFID reader antennas 64 in the space 14 will improve the readability of RFID components 60 also mounted in the space 14. That is, the RFID reader antennas 64 and RFID components 60 that are both mounted in the space 14 will have a more direct line of sight to one another, thereby improving the RF signal strength and, ultimately, the interaction between the RFID tags and antennas. Further, in this case, the walls of the equipment cabinet are useful in enhancing the channeling of RF energy along the space 14 to improve the readability of the RFID components 60.

The above approaches for mounting RFID components 60 and/or RFID reader antennas 64, in the space 14 may also be attractive for data center RFID retrofit or upgrade applications where equipment must be added to cabinets that are already very full. In a similar manner, other RFID hardware advantageously may be mounted using bracket 40. As shown in FIG. 8, both the RFID components 60 and RFID reader antennas 64 may be mounted in the space 14. However, either the components 60, or antennas 64 may be mounted in the space 14 without the other also being mounted in space 14.

It should be emphasized that the above-described embodiments of the present invention, particularly any “preferred” embodiments, are merely possible examples of implementations, merely set forth for a clear understanding of principles of the invention. Many variations and modifications may be made to the above-described embodiments of the invention without departing substantially from the spirit and principles of the invention. All such modifications and variations are intended to be included herein within the scope of this disclosure and the present invention and protected by the following claims.

For example, RFID reader antennas 64 as shown in FIG. 8 may be used in the cabinet as shown in FIG. 1 instead of the RFID reader antennas 62. Also, for example, the equipment cabinet 2 shown in FIG. 8 may include one or more cabinet walls 4, 6, 8, 10, as shown in FIG. 1.

By way of further example, the equipment cabinet 2 may take on a more open configuration. For example, the equipment cabinet 2 may include only an equipment rack 3 either with a base 27 as shown in FIG. 8, or without a base 27. Additionally, such an open equipment cabinet 2 may include a top 29 and may include supports 21 coupling the top 29 with the base 27.

By way of still further example, in general the equipment cabinet 2 may include some form of outer structure disposed adjacent to the equipment rack 3 and that defines, together with the equipment rack 3 a space 14 into which other equipment racks may not be located. That is, such outer structure limits the extent to which the equipment racks 3 of adjacent cabinets 2 may be located near one another. For example, the outer structure may include at least one of a base 27, a support 21, a top 29, and a wall 4, 6, 7, 10. Thusly, there is defined a space 14 adjacent to the equipment rack 3 and outside of the central rack space 6.

What is claimed is:

1. An equipment cabinet comprising:
a front wall having a front opening therein, the front opening having a width;
a side wall, coupled to the front wall;
an equipment rack disposed adjacent to the front wall and to the side wall, the equipment rack having a width and a front face plane, wherein the width of the equipment rack is approximately equal to or larger than the width of the front opening, and the front face plane faces the front opening;
a space disposed between the equipment rack and the side wall, and between the equipment rack and the front wall; and
a mounting bracket comprising a plate and a protrusion, wherein the plate is coupled to one of the equipment rack, the front wall and the side wall, wherein the protrusion is disposed in the space, and further wherein the protrusion has a substantially planar surface, and the substantially planar surface is neither parallel to, nor in the same plane as, the front face plane.

2. The equipment cabinet of claim 1, further comprising RFID hardware coupled to the protrusion.

3. The equipment cabinet of claim 2, wherein the RFID hardware comprises an RFID tag.

4. The equipment cabinet of claim 3, further comprising a second mounting bracket comprising a second plate and a second protrusion, wherein the second plate is coupled to one of the equipment rack, the front wall and the side wall, wherein the second protrusion is disposed in the space, and further comprising an RFID reader antenna coupled to the second protrusion.

5. The equipment cabinet of claim 3, further comprising an RFID reader antenna disposed so as to emit RFID signals into the space.

6. The equipment cabinet of claim 2, wherein the RFID hardware comprises an RFID reader antenna.

7. The equipment cabinet of claim 6, further comprising RFID tags disposed in the space.

8. The equipment cabinet of claim 1, further comprising a patch panel coupled to the protrusion.

9. The equipment cabinet of claim 1, further comprising an adapter module coupled to the protrusion.

10. The equipment cabinet of claim 1, further comprising a piece of equipment coupled to the equipment rack, the equipment comprising a first socket, and the equipment cabinet further comprises a patch panel coupled to the protrusion, a second socket coupled to the patch panel and a cable connected between the first socket and the second socket.

11. An equipment cabinet comprising:
an equipment rack including vertical rails that define a central rack space;
a mounting bracket comprising a plate and a protrusion, wherein the plate is coupled to one of the vertical rails so that the protrusion is disposed outside of the central rack space; and
RFID hardware coupled to the protrusion.

12. The equipment cabinet of claim 11, wherein the RFID hardware comprises at least one of an RFID tag and an RFID reader antenna.

13. The equipment cabinet of claim 11, further comprising:
a wall disposed adjacent to the equipment rack so that a space is disposed between the equipment rack and the wall, wherein the protrusion is disposed in the space.

14. The equipment cabinet of claim 13, wherein the RFID hardware comprises at least one of an RFID tag and an RFID reader antenna.

15. The equipment cabinet of claim 13, wherein the RFID hardware comprises an RFID tag, and the cabinet further comprises an RFID reader antenna disposed so as to emit RFID signals into the space.

16. The equipment cabinet of claim 11, wherein the RFID hardware comprises, an RFID tag, and wherein the equipment cabinet further comprises an RFID reader antenna disposed outside of the central rack space.

17. An equipment cabinet comprising:
an equipment rack including a central rack space;
an outer structure coupled to the equipment rack and disposed outside the central rack space;
a space disposed outside of the central rack space and being defined by the equipment rack and the outer structure;
a mounting bracket comprising a plate and a protrusion, wherein the plate is coupled to one of the equipment rack and the outer structure, wherein the protrusion is disposed in the space; and
RFID hardware coupled to the protrusion.

18. The equipment cabinet of claim 17, wherein the RFID hardware comprises at least one of an RFID tag and an RFID reader antenna.

19. The equipment cabinet of claim 17, wherein the RFID hardware comprises an RFID tag, and wherein the equipment cabinet further comprises an RFID reader antenna disposed so as to emit RFID signals into the space.

20. The equipment cabinet of claim 19, wherein the outer structure includes a wall.
